(19) United States
(12) Patent Application Publication
(10) Pub. No.: US 2021/0152118 A1
(43) Pub. Date: May 20, 2021

(54) WINDOW MOUNTED PHOTOVOLTAIC SYSTEM WITH BRACKETS

(71) Applicant: Hall Labs LLC, Provo, UT (US)

(72) Inventors: David R. Hall, Provo, UT (US); Jerome Miles, Spanish Fork, UT (US); Seth Myer, Eagle Mountain, UT (US)

(73) Assignee: Hall Labs LLC, Provo, UT (US)

(21) Appl. No.: 16/684,588

(22) Filed: Nov. 14, 2019

(51) Int. Cl. H02S 20/26; H02S 30/10; H02S 40/34; H02S 40/42; E06B 7/28; F16B 5/00

(52) U.S. Cl. CPC H02S 20/26; H02S 30/10; F16B 5/00; H02S 40/425; E06B 7/28; H02S 40/34

(57) ABSTRACT

The invention is a photovoltaic system mounted with brackets to the inside surface of a window. The brackets are adhesively attached to the window. The system comprises photovoltaic modules on a substrate along with a sheet of material which is visually similar to the substrate which are both attached by the brackets to the interior surface of a window, facing towards the outside of the building. The light incident side of the substrate with photovoltaic cells faces the exterior of the building facing the sun. Electrical connectors are integrated into the substrate and connected to solar cells within the photovoltaic modules, thus providing electrical connection of the system to external electrical devices or electrical systems near the window that require power.

### TECHNICAL FIELD

This invention relates to photovoltaic systems.

### BACKGROUND

Solar power systems for residential applications typically consist of an array of solar photovoltaic panels mounted to a racking system on the roof of a house. In many instances, a large amount of solar energy is needed to provide power for the entire house. There are some cases where a small amount of electrical power is needed for devices inside the house. A roof top mounted system may be larger than what is really needed for these low power devices or systems.

Disadvantages of traditional roof mounted systems include the fact that the solar panels are on the outside of the house and require a roof penetration to get the wiring from the outside of the house to the interior of the house where the power is needed. These penetrations introduce the possibility for leaks at the penetration that may cause water damage. Another feature of a roof mounted system is that the solar panels are exposed to the elements (rain, wind, snow, hail, tree branches falling on or scraping against) that could be damaging or destructive to the solar panels. Traditional solar power systems are further exposed to temperature extremes that may degrade the performance and shorten the useful life of the solar panels.

There are many cases where power is required near a window on the interior space of a building that does not have power available at the window. This may be desirable even in houses that have a traditional solar power system on the roof of the house. Examples of devices that may require power near or at a window or sliding door include automated (motor driven) window coverings, along with motorized window or sliding door systems that open and close a window or door.

By placing the solar photovoltaic modules on the inside of the house at or near the window, many of the disadvantages of a roof mounted system may be resolved. The solar modules are on the inside of the house and are therefore not exposed to the elements and temperature extremes, thus improving performance and extending the life of the solar modules. No roof penetrations are required so there is no risk of water intrusion causing damage.

There are known interior mounted solar photovoltaic systems that include a solar panel or solar PV cells mounted near a window, in between the panes of window glass, or even inside the window glass itself. These known systems overcome many of the disadvantages of a traditional roof mounted system. However, most of these systems are expensive to manufacture and in many cases are not retrofittable to existing windows.

For example, in some of the known interior mounted solar photovoltaic systems, the solar modules are enclosed in a frame that is attached to a headrail above a window or attached to a window frame. In this example, there are costs associated with the manufacturing of the frame itself that structurally supports the solar cells within the modules.

### SUMMARY

In one aspect, the invention is a photovoltaic system mounted with brackets to the inside surface of a window. The system comprises photovoltaic modules on a substrate along with a sheet of material which is visually similar to the substrate which are both attached to the interior surface of a window by adhesively attached brackets, facing towards the outside of the building. The light incident side of the substrate with photovoltaic cells facing the exterior of the building facing the sun. Electrical connectors are integrated into the substrate and connected to solar cells within the photovoltaic modules, thus providing electrical connection of the system to external electrical devices or electrical systems near the window that require power.

In a preferred embodiment, the photovoltaic system mounted with brackets to the inside surface of a window may comprise photovoltaic modules on a substrate along with a sheet of material which is visually similar to the substrate which may both be attached to the interior surface of a window by adhesively attached brackets, facing towards the outside of the building. The light incident side of the substrate with photovoltaic cells may face the exterior of the building facing the sun. Electrical connectors may be integrated into the substrate and connected to solar cells within the photovoltaic modules, thus providing electrical connection of the system to external electrical devices or electrical systems near the window that require power.

This invention has been developed in response to the present state of the art and, in particular, in response to the problems and needs in the art that have not yet been fully solved by currently available systems and methods. Features and advantages of different embodiments of the invention will become more fully apparent from the following description and appended claims or may be learned by practice of the invention as set forth hereinafter.

Consistent with the foregoing, a window mounted photovoltaic system with brackets is disclosed. The objectives of the system are to provide a photovoltaic system mounted with brackets to the inside surface of a window. The system comprises photovoltaic modules on a substrate along with a sheet of material which is visually similar to the substrate which are both attached to the interior surface of a window by adhesively attached brackets, facing towards the outside of the building. The light incident side of the substrate with photovoltaic cells facing the exterior of the building facing the sun. Electrical connectors are integrated into the substrate and connected to solar cells within the photovoltaic modules, thus providing electrical connection of the system to external electrical devices or electrical systems near the window that require power.

In a preferred embodiment, A window mounted photovoltaic system may include a photovoltaic module. The photovoltaic module may include a generally planar substrate having a first and second major sides. The photovoltaic module may further include two or more photovoltaic cells with one side on the first major side of the substrate. The system may also include one or more brackets adhesively attached to an interior surface of a window with a layer of contact adhesive, wherein the one or more brackets may be configured to mechanically engage the photovoltaic module to hold the photovoltaic module in place with a light incident side facing the interior surface of the window.

In an embodiment, the invention may include a release coating covering the contact adhesive. The invention may also have a total surface area of the first side of the substrate that is larger than a photovoltaically active area of the one or more photovoltaic cells, thus creating a photovoltaically non-active border area on the first side. The border area may be aligned under a retaining portion of the brackets allowing the photovoltaically active area of the photovoltaic cells to not be shaded by the brackets.

In other embodiments, the invention may include an insulated strip of material that may be attached to the border area of the substrate, the strip being compressed when the photovoltaic module is placed into the brackets and thus insulating the area between the photovoltaic module and window interior surface from air flow, dust particles and any other intrusions that may inhibit the function of the system.

In some embodiments, the photovoltaic module may be made of a flexible thin-film solar material having the ability to bend up to 30 degrees. The photovoltaic module may also, in another embodiment, be made of a semi-flexible material having the ability to bend up to 5 degrees.

In an embodiment, the photovoltaic module may be held tight to and be in full contact with the window interior surface. In another embodiment, at least one of the brackets may have a hole in it allowing an electrical connection to be made to the photovoltaic module.

In certain embodiments, a base section of the bracket may be thick enough to create a space between the interior surface of the window and the window facing surface of the photovoltaic module, thus creating an open area allowing air to flow between the module and the window.

In an embodiment, the mechanical engagement of the photovoltaic module to the brackets may include at least one of: snaps, clasps, hook and loop fasteners, zippers, magnets, magnetic plates, metal plates, screw type, sliding connectors, and channels. The photovoltaic module may also include a mechanical attachment member partially embedded in the substrate.

In another embodiment, the brackets may also include a channel opening that is wider at an insertion point of the photovoltaic module and more narrow at a position where the photovoltaic module is fully inserted, thus creating a friction fit that holds the photovoltaic module in place once it has been fully inserted.

The invention may, in an embodiment, include a first terminal and a second terminal which are in electrical communication with the photovoltaic cells. The terminals may be disposed in a first electrical connector which is supported on the substrate. At least one electrical conductor with a second electrical connector may be plugged into the first electrical connector, wherein the conductor may be extended to an electrical device or circuit. The conductor may be extended to a motorized window opener. The photovoltaic module may provide power to the motorized window opener. The conductor may be extended to a motorized window covering, and the photovoltaic module may provide power to the motorized window covering.

In an embodiment, the window may be a sliding door with at least one section of transparent glazing material.

The system may also include a sheet of material that looks visually similar to the substrate; whereby the sheet of material may be deployed adjacent to the substrate by attachment to the interior surface of the window with contact adhesive.

Further aspects and embodiments are provided in the foregoing drawings, detailed description and claims.

### BRIEF DESCRIPTION OF THE DRAWINGS

The following drawings are provided to illustrate certain embodiments described herein. The drawings are merely illustrative and are not intended to limit the scope of claimed inventions and are not intended to show every potential feature or embodiment of the claimed inventions. The drawings are not necessarily drawn to scale; in some instances, certain elements of the drawing may be enlarged with respect to other elements of the drawing for purposes of illustration.

FIG. 1 is a section view of a house showing the sun's rays shining on to a window mounted photovoltaic module.

FIG. 2A is an isometric view of a window with the photovoltaic system, according to one example embodiment.

FIG. 2B is a side section view of a photovoltaic module inside a bracket.

FIG. 2C is a side section view of another embodiment of a photovoltaic module inside a bracket.

FIG. 2D is a side section view of a photovoltaic module inside brackets adjacent to a sheet of material which is visually similar to the module.

FIG. 3A is a front view of a window on the interior of a house showing the photovoltaic system and electrical device.

FIG. 3B is a side section view of a window with photovoltaic module mounted to the top of the window.

FIG. 4A is a front view of a window on the interior of a house showing another embodiment of the photovoltaic system mounted to a window.

FIG. 4B is a side section view of a window with photovoltaic module vertically mounted along the side of the interior pane of the window.

FIG. 5A is a side section view of another embodiment of a window with photovoltaic module mounted to the top of the window.

FIG. 5B is a side section view of an additional embodiment of a window with photovoltaic module mounted to the top of the window.

FIG. 5C is a side section view of a window and a photovoltaic module with an insulated air gap between the window and module.

FIG. 5D is a front view of a window on the exterior of a house showing the photovoltaic module with an insulated border around the perimeter of the module.

FIG. 6A is a partial side section of an enlarged view of a window with photovoltaic module mounted to the top of the window.

FIG. 6B is a side section view of a photovoltaic module being attached to a window.

FIG. 7A is a partial side section of an enlarged view of another embodiment of a window with photovoltaic module mounted to the top of the window.

FIG. 7B is a front view of a window on the exterior of a house showing the photovoltaic module with air flow.

FIG. 8 is an isometric view of a bracket with release coating covering the contact adhesive.

FIG. 9 is a perspective view of a sliding window/door system with a window covering.

FIG. 10 is a perspective view of a motorized sliding window/door system.

FIG. 11A is front view of two brackets with a module sliding into the brackets.

FIG. 11B is a front view of a module fully seated into two brackets.

FIG. 12A is front view of a module sliding into L shaped brackets.

FIG. 12B is a front view of a module fully seated into the two L shaped brackets.

### DETAILED DESCRIPTION

The following description recites various aspects and embodiments of the inventions disclosed herein. No particular embodiment is intended to define the scope of the invention. Rather, the embodiments provide non-limiting examples of various compositions, and methods that are included within the scope of the claimed inventions. The description is to be read from the perspective of one of ordinary skill in the art. Therefore, information that is well known to the ordinarily skilled artisan is not necessarily included.

Reference throughout this specification to “one embodiment,” “an embodiment,” or similar language means that a particular feature, structure, or characteristic described in connection with the embodiment is included in at least one embodiment. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

### Definitions

The following terms and phrases have the meanings indicated below, unless otherwise provided herein. This disclosure may employ other terms and phrases not expressly defined herein. Such other terms and phrases shall have the meanings that they would possess within the context of this disclosure to those of ordinary skill in the art. In some instances, a term or phrase may be defined in the singular or plural. In such instances, it is understood that any term in the singular may include its plural counterpart and vice versa, unless expressly indicated to the contrary.

As used herein, the singular forms “a,” “an,” and “the” include plural referents unless the context clearly dictates otherwise. For example, reference to “a substituent” encompasses a single substituent as well as two or more substituents, and the like.

As used herein, “for example,” “for instance,” “such as,” or “including” are meant to introduce examples that further clarify more general subject matter. Unless otherwise expressly indicated, such examples are provided only as an aid for understanding embodiments illustrated in the present disclosure and are not meant to be limiting in any fashion. Nor do these phrases indicate any kind of preference for the disclosed embodiment.

“Solar modules” and “photovoltaic modules” as referred to throughout this document refer to an electrical module that produces energy, collects energy, produces power, transmits power, conducts electricity, communicates energy, converts energy from one form to another, and combinations of one or more of the foregoing.

The term “flexible” when referencing a photovoltaic module describes a flexible thin-film solar material having the ability to bend up to 30 degrees without breaking. Flexible solar panels are preferably built with the solar collecting material impregnated into a thin mylar film that is affixed to a flexible aluminum substrate.

“Semi-flexible” refers to a photovoltaic module that is comprised of a semi-flexible material having the ability to bend up to 5 degrees without breaking. Semi flexible solar panels typically comprise solar cells that may not bend too far without being damaged or breaking. They are preferably built with the solar collecting material impregnated into a less flexible substrate such as fiberglass.

One advantage of the the preferred embodiment is that solar modules are mounted to brackets on the actual window surface on the inside of the house facing out towards the outside of the house, being exposed to the sun.

In this fashion, the window itself becomes the support structure for the brackets that support solar modules, thus minimizing the amount of material within the solar module that is needed to structurally support the cells. The structural framework supporting a substrate or planar material upon which the solar cells are mounted to may be minimized. The window structure supports simple brackets into which the solar modules may be installed.

In some cases, the solar module may be comprised of a semi-flexible material. In this case, the semi-flexible nature of the material allows it to be easily handled and installed onto the surface of a window. The module may be slid into brackets that have a peel and stick adhesive feature that allows them to be adhesively attached to the window surface.

Semi-flexible solar modules are also lighter and thinner than rigid solar modules yet have a more robust construction than flexible solar modules. Semi-flexible solar modules allow flexibility to bend up to 5 degrees. The minimal flexibility of the semi-flexible solar modules may provide enough flexibility in many cases to allow them to be slid into the brackets in a slightly bent position. Once they are slid into the brackets, they may then relax into a normal straight and extended position, allowing the brackets to retain the modules in place as required.

In summary, the key advantages posited for the preferred embodiment of the present invention include a system that:
provides a cost-effective solar power system that may provide power to electrical devices or systems near a window in a house;
simplifies the support structure, because the window itself is the support for brackets that allow attachment of the modules to an inside surface of a window;
provides a solar power system that may be installed in the interior space of a house;
may be retrofitted to an existing window;
allows the solar modules to be mounted to the inside surface of a window;
provides for modules to be removed from the brackets for cleaning the window;
brackets may be directly attached to the window without a separate support structure;
can be configured to provide an air gap area between the modules and the window for air flow;
simplifies installation by providing a peel and stick adhesive system that allows the attachment of brackets for mounting the modules to a window; and
further simplifies the installation by making the electrical connection of the modules to an electrical device or electrical interconnection system by a simple plug-in connection.

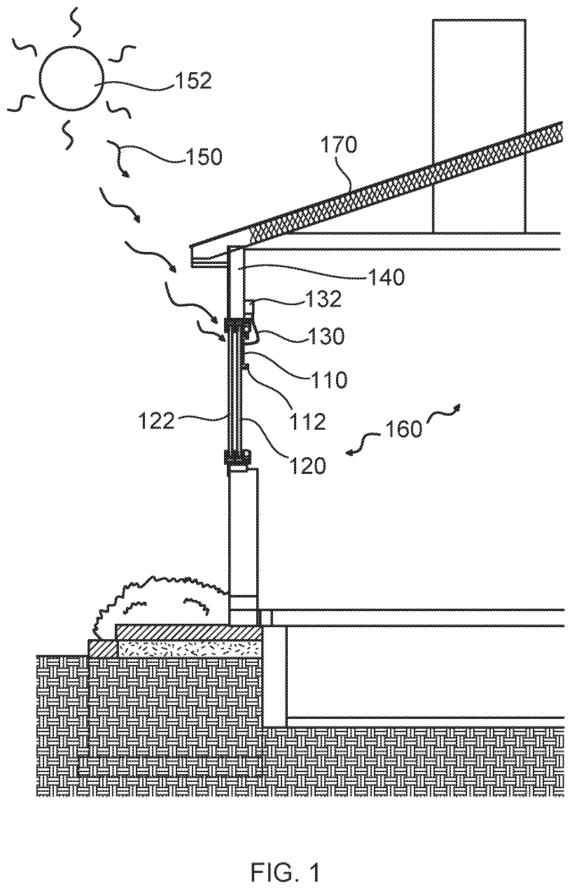

Referring to the drawings, FIG. 1 is a section view of a house showing the sun's rays shining on to a window mounted photovoltaic module. A section view of house 170 is shown with a window installed in exterior wall 140. Photovoltaic module 110 is located on the interior 160 of the house 170 on an inside surface of an interior surface of window 120. Photovoltaic module 110 is held in place by bracket 112. Sun 152 is shown with solar energy rays 150 shining on to the light incident side of photovoltaic module 110, passing through exterior pane 122 and window 120. The photovoltaic module 110 produces electrical power which is supplied via electrical conductor 130 to electrical device 132. In this embodiment, the electrical device 132 is directly above the photovoltaic module 110. Since the electrical device 132 is located above the window, there are no readily accessible electrical outlets or receptacles near the upper part of wall 140. This necessitates the provision of power from the window mounted photovoltaic system. The electrical device 132 may comprise a motor or actuator that is wirelessly controlled from a wireless network. The wireless network may be Bluetooth, WiFi or other wireless technology that does not require wiring to be installed. In this way, the system is completely autonomous without the need of running additional wires on the interior of the house beyond the wiring 130 that connects the photovoltaic system to the device 132.

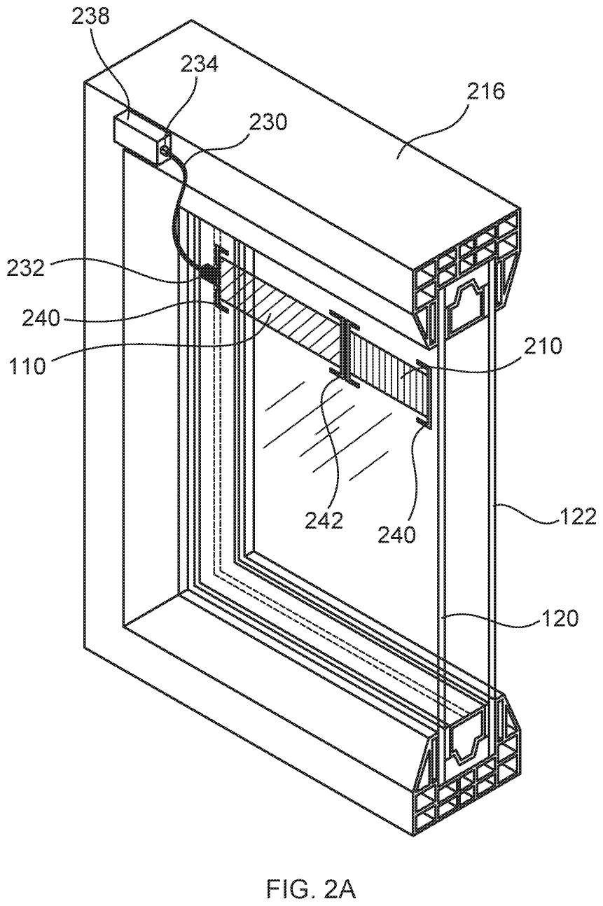

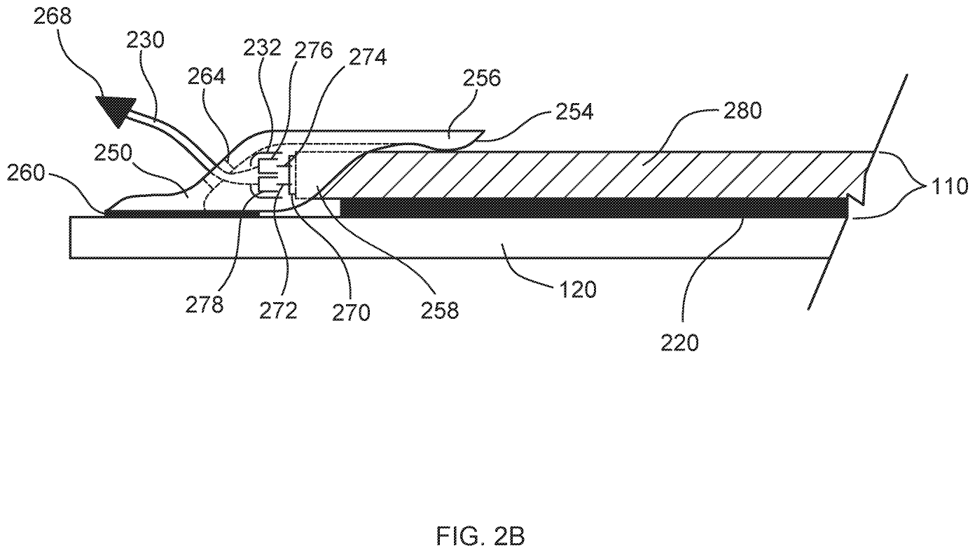

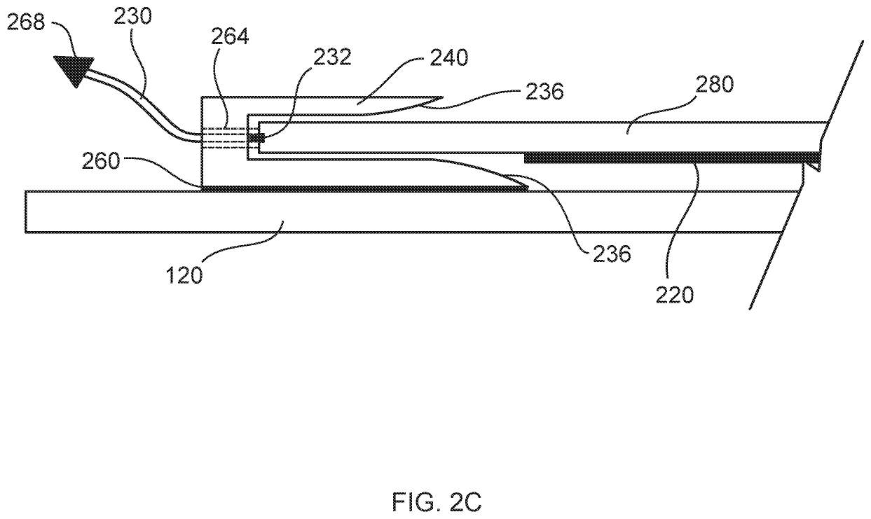

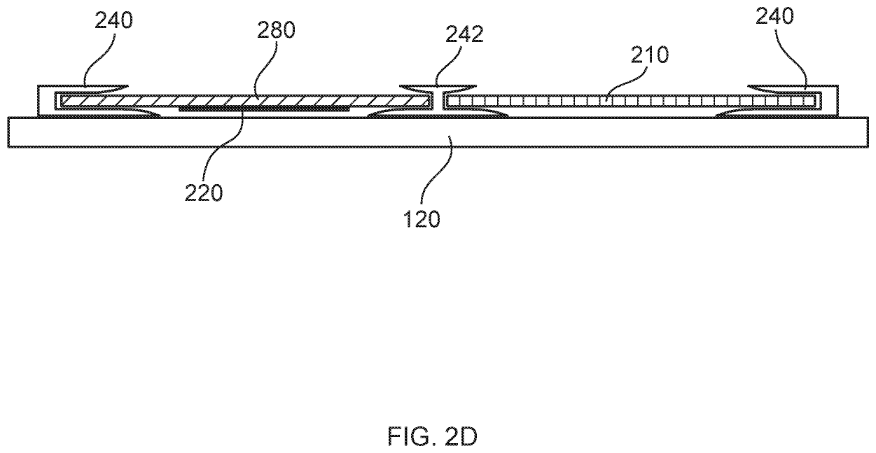

FIG. 2A is an isometric view of a window with the photovoltaic system, according to one example embodiment. In this drawing, the window frame 216 is shown with electrical device 238 mounted to the header of window frame 216. Electrical conductor 230 electrically connects via second connector 232 to photovoltaic module 110. Electrical conductor 230 also electrically connects to electrical device 238 via third electrical connector 234. Photovoltaic module 110 is held in place by end brackets 240 and center brackets 242. Brackets 240 and 242 are adhesively mounted directly to interior surface of window 120. Exterior pane 122 is shown on the exterior side of the window. Sheet of material 210 looks visually similar to the photovoltaic module 110 and is mounted directly adjacent to the photovoltaic module 110 as shown. This makes the entire top section of window 120 have a unified dark (photovoltaic module 110 is a dark color in this embodiment) band of color extending across the entire top section of the window 120 when viewed from the exterior of the house (looking towards the window). This provides for an aesthetically pleasing look that does not detract from the overall look of the window 216 when viewed from the exterior of the house. In this embodiment, the interior side of both photovoltaic module 110 and sheet of material 210 may be white in color so as to look aesthetically pleasing on the interior of the house. The surface of the interior of photovoltaic module 110 and sheet of material 210 may also be painted to match the interior decor of the house. The sheet of material 210 may be comprised of plastic, cardboard, paper, or any other material that may be manufactured for a lower price than the photovoltaic module 110. The sheet of material 210 may be supplied in a long piece that may be cut on site to fit the size of the window. In this way, the photovoltaic system comprising the photovoltaic module 110 and sheet of material 210 may be adjusted to fit any window size.

FIG. 2B is a side section view of a photovoltaic module inside bracket 250. The bracket 250 is attached to the surface of window 120 with adhesive 260. The photovoltaic module 110 comprises a substrate 280 and a photovoltaically active section 220. The photovoltaically active section 220 has its light incident side facing the window 120 surface. Bracket 250 has side flanges 258 that retain the photovoltaic module 110 inside the bracket 250 as shown. Bracket 250 further includes a self-retaining member 256 that is pre-loaded with a compressive force to retain the photovoltaic module 110 in place once it has been inserted into bracket 250 by pushing against the surface of substrate 280, thus forcing the photovoltaic module 110 tight against the window 120 so that the photovoltaically active section 220 is flush with the surface of window 120. Self-retaining member 256 further comprises a tapered edge 254 that allows the photovoltaic module 110 to be slid into bracket 250 pushing against the pre-loaded force of self-retaining member 256 creating a compressive force, thus clamping the photovoltaic module 110 into place against the window 120. Bracket 250 also includes a hole 264 in it, allowing first electrical connector 270 to be connected to second electrical connector 232, thus electrically connecting the photovoltaic module 110 to first terminal 272 and second terminal 274 disposed inside first electrical connector 270. Electrical conductors 230 are connected to third terminal 276 and fourth terminal 278 which are disposed inside second electrical connector 232. Electrical conductors 230 are extended 268 to an electrical circuit or device.

FIG. 2C is a side section view of another embodiment of a photovoltaic module inside bracket 240. Substrate 280 is shown with photovoltaically active side of photovoltaically active section 220 facing the surface of window 120. Bracket 240 is shaped with tapered edges 236 to guide the insertion of substrate 280 into bracket 240. Bracket 240 also includes a hole 264 in it, allowing connection of conductors 230 and second electrical connector 232 to the module. Electrical conductors 230 are extended 268 to an electrical circuit or device. Bracket 240 is attached to the surface of window 120 by adhesive 260.

FIG. 2D is a side section view of a photovoltaic module inside brackets adjacent to a sheet of material which is visually similar to the module. Sheet of material 210 looks visually similar to substrate 280 with photovoltaically active section 220 and is mounted directly adjacent to the photovoltaic module as shown. End brackets 240 and center bracket 242 are shown with the center bracket 242 attaching both the photovoltaic module and the sheet of material 210 to the surface of window 120.

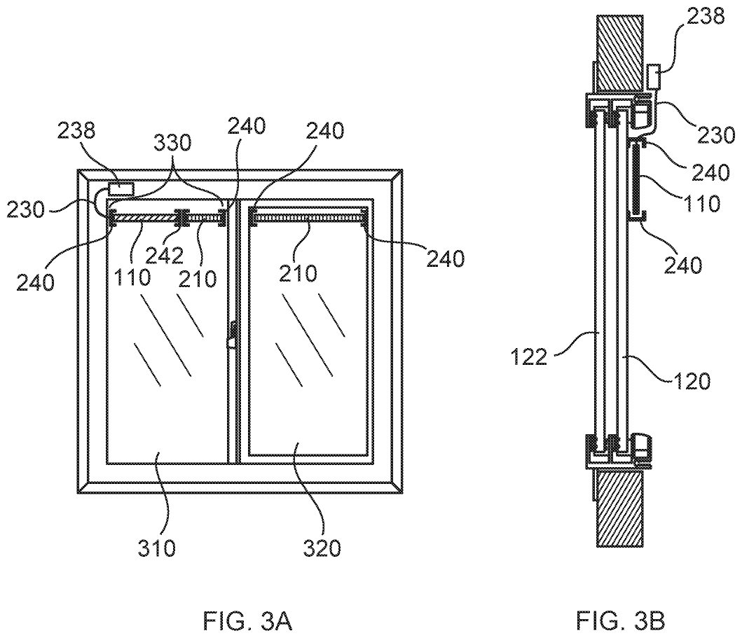

FIG. 3A is a front view of a window on the interior of a house showing the photovoltaic system and electrical device 238. Photovoltaic module 110 is shown attached to fixed window 310 by end brackets 240 and center bracket 242. When sliding window 320 is being opened or closed, the wiring 230 that is extended to electrical device 238 is not impacted by the travel of sliding window 320. The side of module 110 and sheet material 210 facing the interior of the house is white in color. The combined overall look 330 of module 110 and material 210 is aesthetically pleasing and looks like one continuous white component. An additional sheet material 210 may be mounted to the top of sliding window 320 as shown. This makes the overall look consistent between the two windows.

FIG. 3B is a side section view of a window with photovoltaic module 110 mounted to the top of the window 120. Exterior pane 122 faces the exterior of the house and interior pane 120 faces the interior of the house. Photovoltaic module 110 is attached to the interior surface of window 120 with brackets 240. Wiring 230 is shown running from photovoltaic module 110 up to electrical device 238.

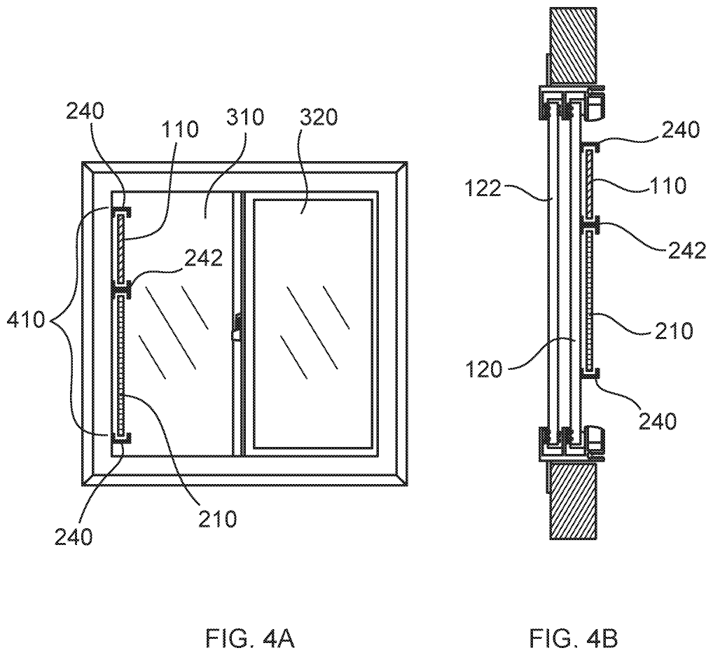

FIG. 4A is a front view of a window on the interior of a house showing another embodiment of the photovoltaic system mounted to a window. Photovoltaic module 110 is shown running vertically rather than horizontally along one side of fixed window 310. Sliding window 320 is also shown. Photovoltaic module 110 and sheet material 210 are attached to fixed window 310 by end brackets 240 and center bracket 242. The side of module 110 and sheet material 210 facing the interior of the house is white in color. The combined overall look 410 of module 110 and sheet material 210 is aesthetically pleasing and looks like one continuous white component.

FIG. 4B is a side section view of a window with photovoltaic module 110 vertically mounted by end brackets 240 and center bracket 242 along the side of window 120. Photovoltaic module 110 and sheet material 210 are attached to fixed window 310 by end brackets 240 and center bracket 242. Exterior pane 122 faces the exterior of the house and interior surface of window 120 faces the interior of the house.

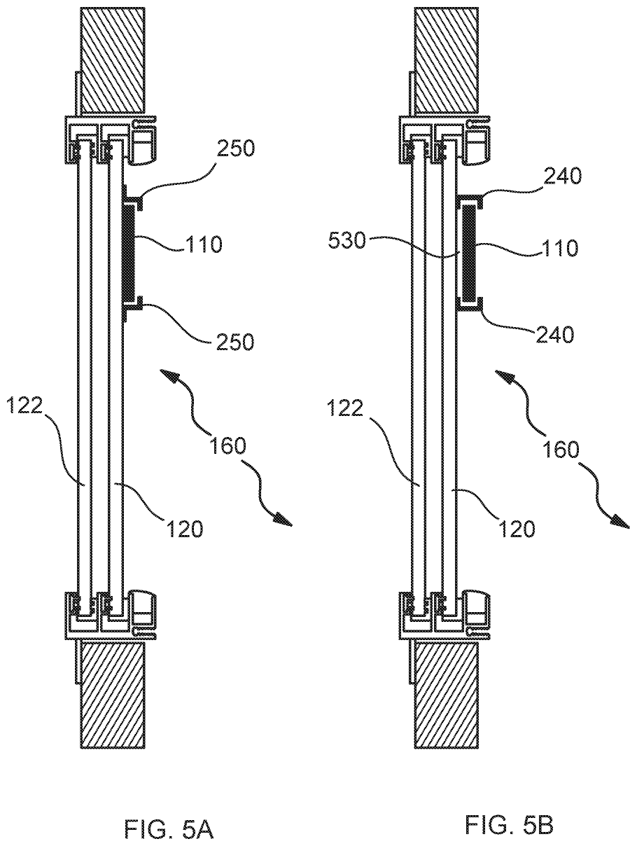

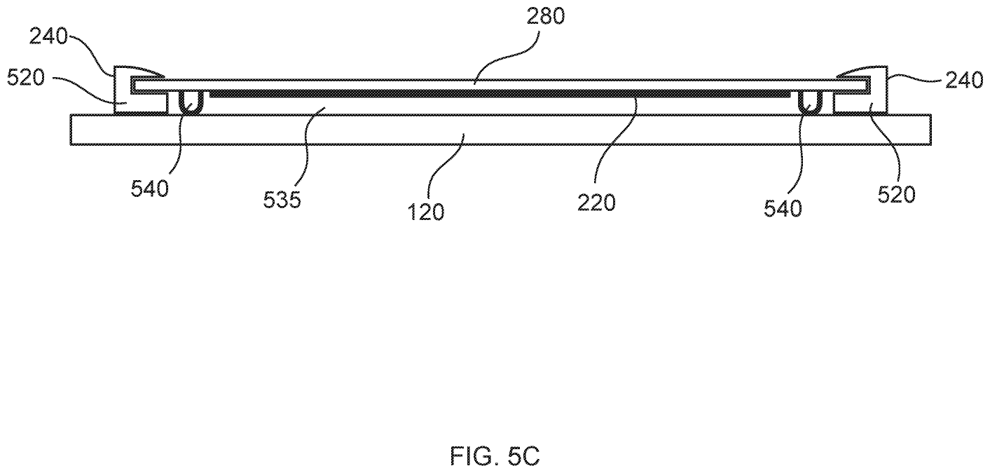

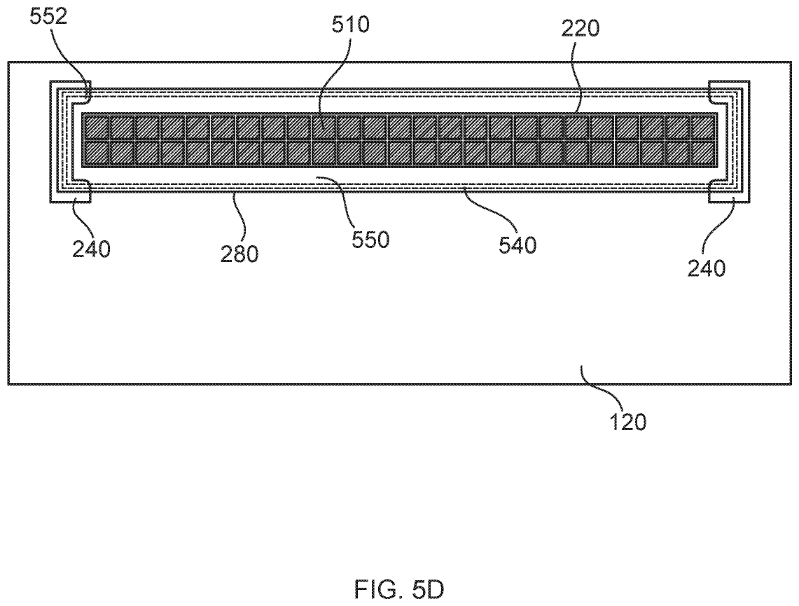

FIG. 5A is a side section view of another embodiment of a window with photovoltaic module 110 mounted to the top of the window. Exterior pane 122 faces the exterior of the house and window 120 faces the interior of the house. Photovoltaic module 110 is attached to interior surface of window 120 by brackets 250. In this embodiment the photovoltaic module 110 is held by brackets 250 tight against the interior surface of window 120. The interior space 160 is shown.

FIG. 5B is a side section view of an additional embodiment of a window with photovoltaic module 110 mounted to the top of the window. Exterior pane 122 faces the exterior of the house and the interior surface of window 120 faces the interior of the house. Photovoltaic module 110 is attached to the interior surface of window 120 by brackets 240. In this embodiment the photovoltaic module 110 is held away from the interior surface of window 120 by brackets 240 creating open space 530 between photovoltaic module 110 and the interior surface of window 120. The interior space 160 is shown.

FIG. 5C is a side section view of a window and a photovoltaic module with an insulated air gap between the window and module. Brackets 240 are shown holding substrate 280 in place. In this embodiment, each bracket 240 has a thick base section 520 creating a space 535 between the interior surface of the window 120 and the window facing surface of the photovoltaic active section 220, thus creating an open area between the module and the window 120. In this embodiment, the window facing side of the substrate 280 further includes insulated strip of material 540 which is attached to the border area of the substrate 280, the strip being compressed when the photovoltaic module is placed into the brackets 240 and thus insulating the area between the photovoltaic module and window interior surface from air flow, dust particles and any other intrusions that may inhibit the function of the system.

FIG. 5D is a front view of a window on the exterior of a house showing the photovoltaic module with an insulated border around the perimeter of the module. Brackets 240 hold substrate 280 close to the interior surface of window 120. Insulated strip of material 540 is attached to the border area 550 of the substrate 280 and is compressed in this example embodiment. The insulated strip of material 540 is being held in a compressed condition by brackets 240. The total surface area of the first side of the substrate 280 is larger than the photovoltaically active area 220 of the one or more photovoltaic cells 510. Border area 550 is not photovoltaically active. A top section 552 of brackets 240 holds the substrate 280 tight against the insulated strip of material 540 thus compressing the insulated strip of material 540.

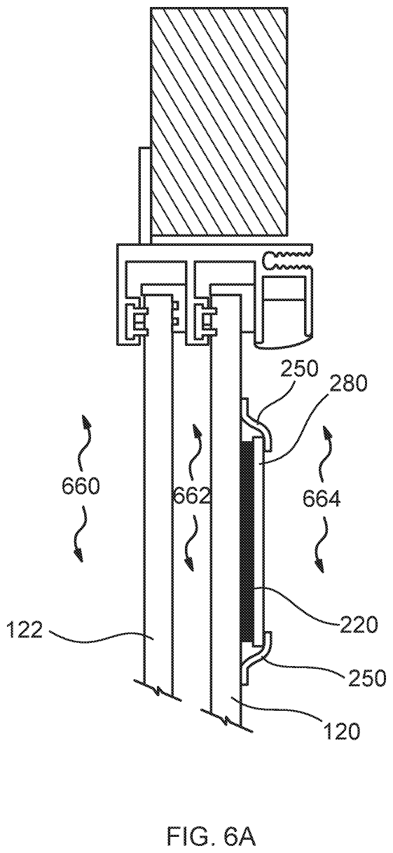

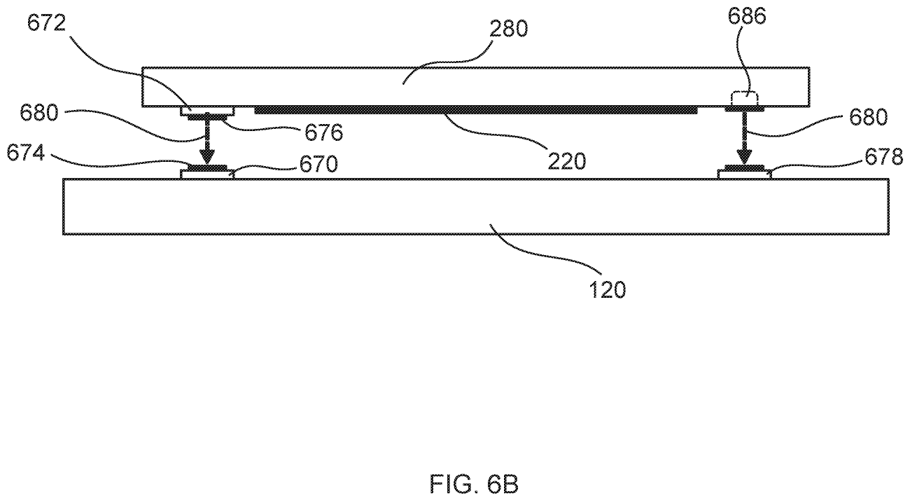

FIG. 6A is a partial side section of an enlarged view of a window with photovoltaic module mounted to the top of the window. Exterior pane 122 faces the exterior of the house and interior surface of window 120 faces the interior of the house. Substrate 280 is attached to interior surface of window 120 by brackets 250. In this embodiment, the photovoltaically active area 220 is held tight against the interior surface of window 120 by brackets 250. Planar substrate 280 is shown with photovoltaically active area 220 comprising photovoltaic cells attached to the substrate 280. Substrate 280 may be a circuit board that has photovoltaic cells attached to it. The border surrounding the photovoltaic cells may be a part of this substrate 280. Exterior temperature 660 is higher in the Summer than temperature 662 between exterior pane 122 & interior surface of window 120. Temperature 664 on the interior of the house is lower than both temperatures 660 and 662. Temperature 530 between interior surface of window 120 and photovoltaically active side 220 is also lower than both temperatures 660 and 662. In this example embodiment, the performance of photovoltaically active side 220 is improved by its location next to the glass. In this embodiment, the proximity of the photovoltaic module 110 to the interior surface of window 120 enhances the production over modules that are not as close to the glass. This is because the efficiency of the photovoltaic module 110 is enhanced when the temperature differential is greater between the light incident photovoltaically active side 220 and the back side of substrate 280. In this embodiment, the closer the photovoltaic cells are to the glass, the greater the power production will be. In a like manner, on Winter days the temperature near the window is higher since it is closer to the solar radiation which produces heat via convection. Conductive heat is also transferred through window 120 to the photovoltaically active side 220, the photovoltaically active side 220 being in contact with the interior surface of window 120.

FIG. 6B is a side section view of a photovoltaic module being attached to a window. Substrate 280 is shown as it is being attached 680 to brackets 670 and 678. Brackets 670 and 678 are adhesively attached to window 120. Photovoltaically active area 220 is also shown. In this embodiment, bracket 672 with mechanical engagement member 676 may be comprised of at least one of: snaps, clasps, hook and loop fasteners, zippers, magnets, magnetic strips, metal plates, screw type, sliding connectors, and channels. In another embodiment, an embedded mechanical attachment member 686 may be partially embedded in the substrate 280 as shown.

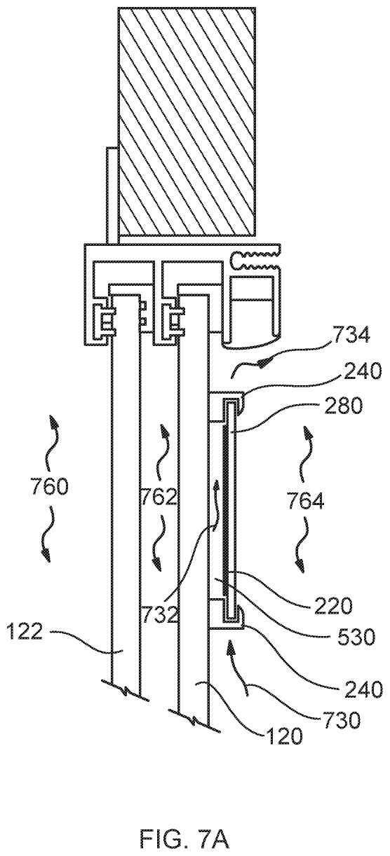

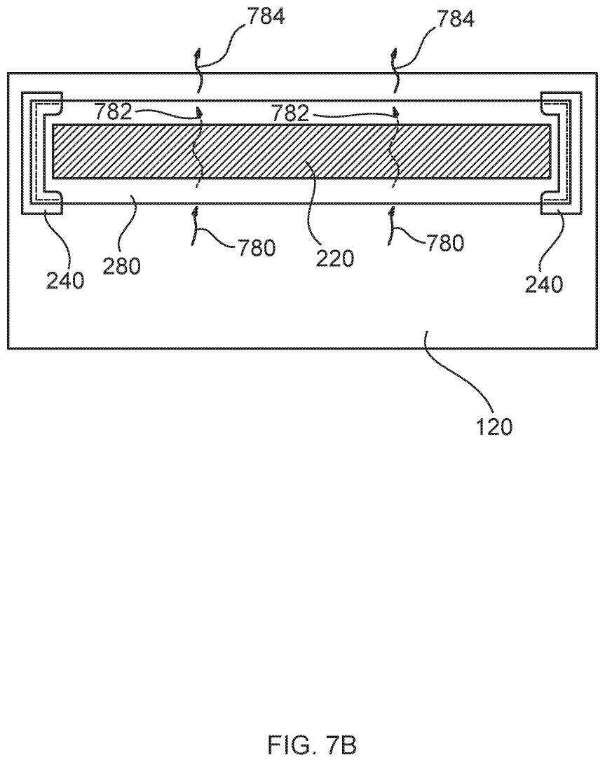

FIG. 7A is a partial side section of an enlarged view of another embodiment of a window with photovoltaic module mounted to the top of the window. Exterior pane 122 faces the exterior of the house and interior surface of window 120 faces the interior of the house. Substrate 280 is held in place near window 120 by brackets 240. In this embodiment, planar substrate 280 is shown with photovoltaically active area 220 comprising photovoltaic cells attached to the substrate 280. Substrate 280 may be a circuit board that has photovoltaic cells attached to it. The border surrounding the photovoltaic cells may be a part of this substrate 280. Exterior temperature 760 is higher in the Summer than temperature 762 between exterior pane 122 & interior surface of window 120. Temperature 764 on the interior of the house is lower than both temperatures 760 and 762. The temperature between interior surface of window 120 and photovoltaically active area 220 is also lower than both temperatures 760 and 762. The performance of photovoltaically active area 220 may be improved by its location near the interior surface of window 120. In this embodiment, the proximity of the photovoltaic module 110 to the interior surface of window 120 enhances the production over modules that are not as close to the glass. This is because the efficiency of the photovoltaic module 110 is enhanced when the temperature differential is greater between the light incident side (photovoltaically active side) of the photovoltaically active area 220 and the back side (substrate 280). The closer the photovoltaic cells are to the glass, the greater the power production will be. In this embodiment, brackets 240 allow the natural convection of heat created within space 530 to draw air 730 in at the bottom of the system up through the bottom of the system. The air 732 is drawn across the front surface of the photovoltaically active area 220 and drawn up and out through the top of the system as heated air 734 exits. This embodiment may be used in geographical areas that have extremely hot temperatures wherein it will not allow the front facing light incident side of the photovoltaically active area 220 to get too hot. The natural cooling of the air flow 732 will keep the photovoltaically active area 220 cool.

FIG. 7B is a front view of a window on the exterior of a house showing the photovoltaic module with air flow. Photovoltaically active area 220 is shown mounted to substrate 280. In this embodiment, brackets 240 hold substrate 280 away from the interior surface of window 120 creating an open area for cool air 780 to naturally be drawn in by solar heated air 782 and convectively heated air 784 exiting the top of the system.

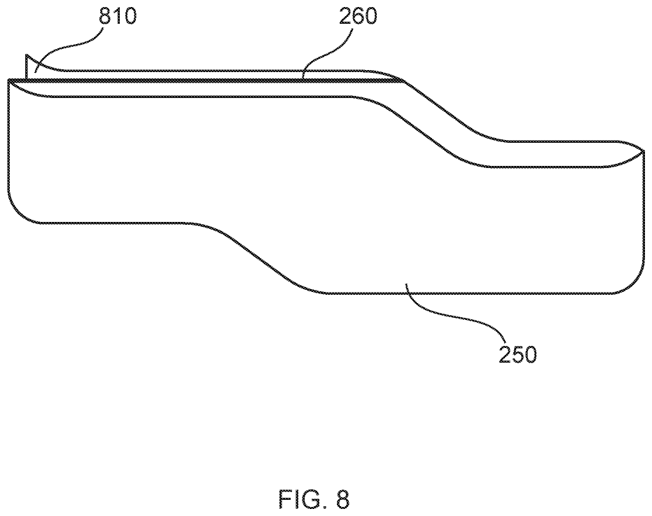

FIG. 8 is an isometric view of a bracket with release coating covering the contact adhesive. Bracket 250 is shown with release coating 810 being partially removed, exposing adhesive 260. Once the release coating 810 has been completely removed, the exposed adhesive 260 may be pressed against the interior surface of a window, thus adhesively attaching bracket 250 to the window.

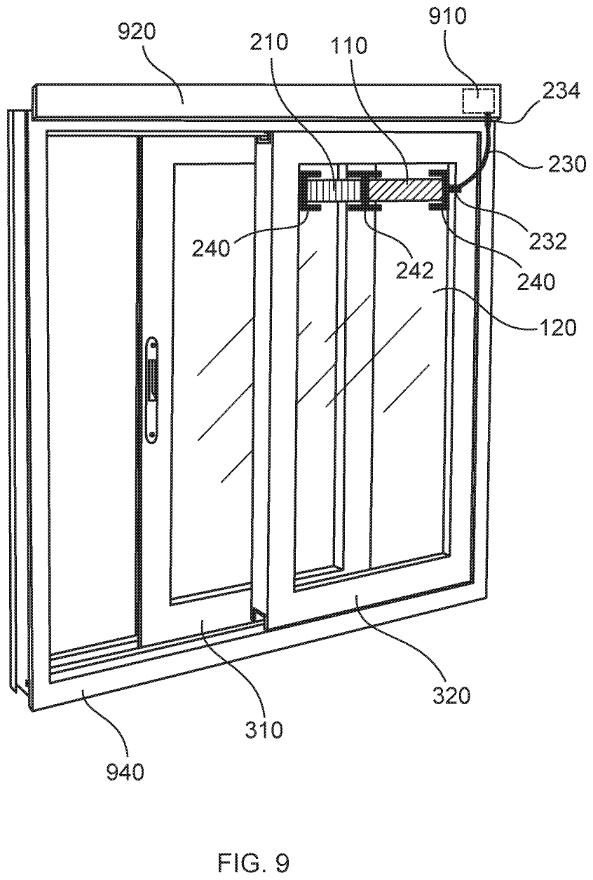

FIG. 9 is a perspective view of a sliding window/door system with a window covering 920. The window covering can be in the form of automated blinds, such as those shown in U.S. Pat. No. 9,540,871, entitled MOTORIZED GEARBOX ASSEMBLY WITH THROUGH-CHANNEL DESIGN. The window covering can also be in the form of an automated roller shade, such as that shown in U.S. Published Patent Application No. 2018-0266176 and entitled Motorized Roll-Up Window Shade. In this embodiment, the window 120 is a sliding door 310 with at least one section of transparent glazing material. Interior surface of stationary section 320 is shown with photovoltaic module 110 and material 210 being shown near the top of interior surface of window 320. Photovoltaic module 110 and material 210 are held in place by brackets 240 and 242. Connector 232 electrically connects to terminals within connector 232 to photovoltaic module 110 and extends power via conductors 230 to connector 234 which connects to electric motor 910. The motor 910 inside window covering 920 powers a gearbox or mechanical actuator that operates the window covering mechanism. Sliding section 310 is shown within frame 940. The frame 940 together with stationary section 320 and sliding door 310 may comprise a sliding window system or a sliding door system. The system may also comprise other window and door systems that are capable of opening and closing, along with systems that may have motorized systems associated with the window or door that require power to operate.

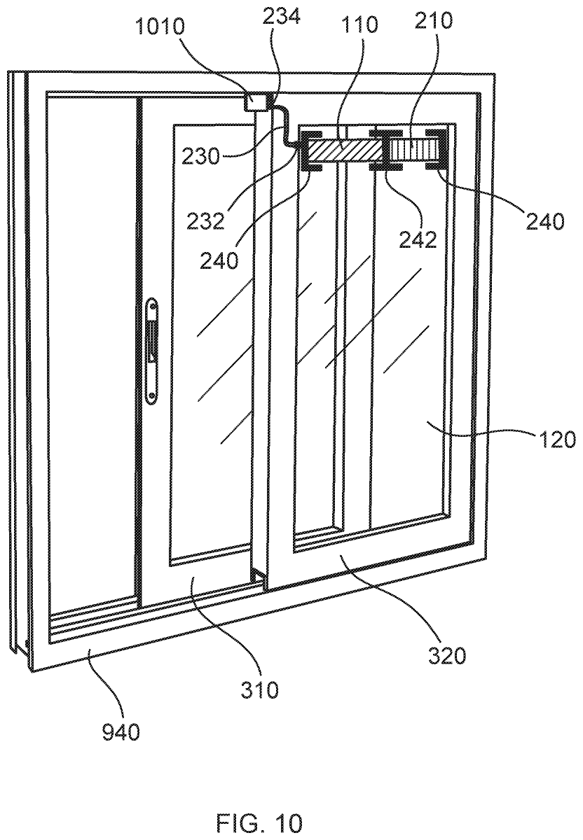

FIG. 10 is a perspective view of a motorized window operator. One preferred such system is described and depicted in U.S. Published Patent Application No. 2019-0003236, entitled Gear-Driven Automated Window or Door System. In this embodiment, the window 120 is a sliding door 310 with stationary section 320 with at least one section of transparent glazing material. Interior surface of stationary section 320 is shown with photovoltaic module 110 and material 210 being shown near the top of interior surface of window 320. Photovoltaic module 110 and material 210 are held in place by brackets 240 and 242. Connector 232 electrically connects to terminals within connector 232 to photovoltaic module 110 and extends power via conductors 230 to connector 234 which connects to electric motor 1010. The motor 1010 powers a mechanical actuator that opens and closes the sliding door 310. Sliding door 310 is shown within frame 940. The frame 940 together with stationary section 320 and sliding section 310 may comprise a sliding window system or a sliding door system. Sliding section 310 is shown within frame 940. The frame 940 together with stationary section 950 and sliding section 310 may comprise a sliding window system or a sliding door system.

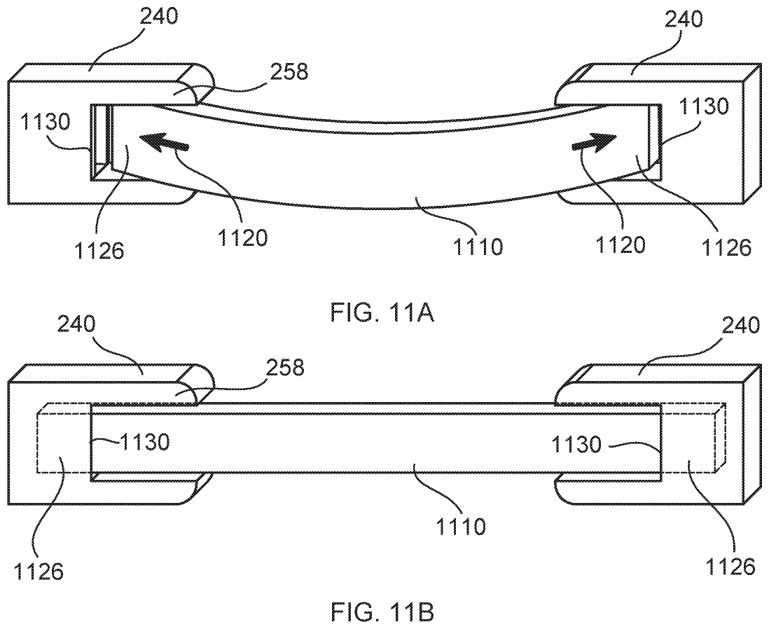

FIG. 11A is front view of two brackets with a module sliding into the brackets. Brackets 240 have already been adhesively attached to a window surface in this example embodiment. Bracket 240 has side flanges 258 that retain the photovoltaic module 1110 inside the bracket 240 and guide the insertion of the photovoltaic module 1110 into the brackets 240. In a first embodiment, the photovoltaic module may be comprised of a flexible thin-film solar material having the ability to bend up to 30 degrees, allowing it to flex as required to be inserted 1120 into the brackets 240. In a second embodiment, the photovoltaic module may be comprised of a semi-flexible material having the ability to bend up to 5 degrees. In this second embodiment, the 5 degree bending degree may be enough to allow sufficient flexibility as required to be inserted 1120 into the brackets 240. The two ends 1126 are pulled towards each other in order to clear the receiving edges 1130 of both brackets 240.

FIG. 11B is a front view of a module fully seated into two brackets. Photovoltaic module 1110 is shown fully inserted into brackets 240 with side flanges 258 retaining it in the proper position being held in place by brackets 240 and receiving edges 1130. With the photovoltaic module 1110 now in a relaxed and straight position, the two ends 1126 are fully inside of the brackets 240 as shown.

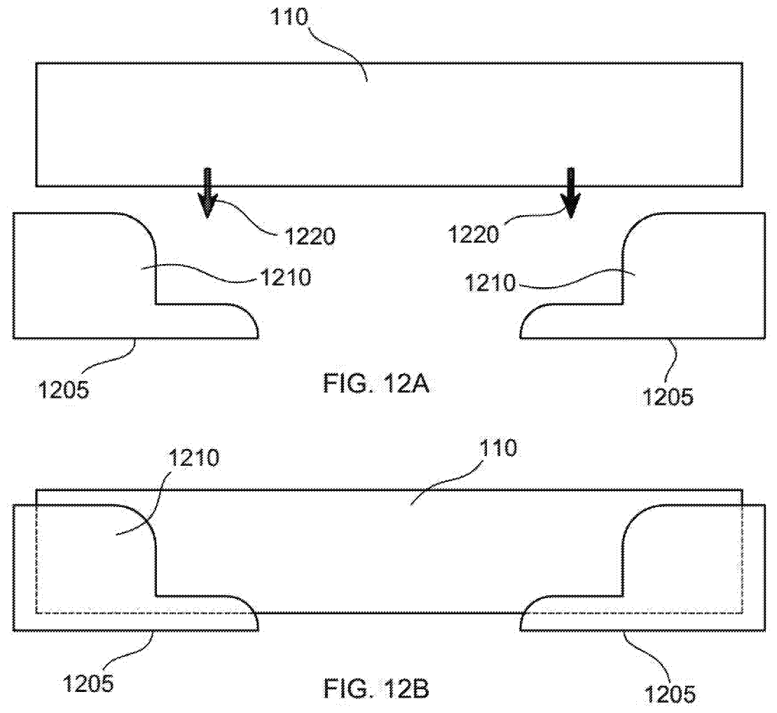

FIG. 12A is front view of a module sliding into L shaped brackets. Photovoltaic module 110 is shown as it is being slid 1220 into L shaped brackets 1205. Brackets 1205 have flanges 1210 that are pre-stressed in a holding position in order to hold photovoltaic module 110 in place one it has been fully inserted. As photovoltaic module 110 is inserted, the position of the flanges moves to allow this insertion, while exerting pressure against the photovoltaic module 110.

FIG. 12B is a front view of a module fully seated into the two L shaped brackets. In this embodiment, the photovoltaic module 110 has been fully inserted into L shaped brackets 1205. Pre-stressed flange 1210 is holding photovoltaic module 110 in place by friction.

The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

All patents and published patent applications referred to herein are incorporated herein by reference. The invention has been described with reference to various specific and preferred embodiments and techniques. Nevertheless, it is understood that many variations and modifications may be made while remaining within the spirit and scope of the invention.

What is claimed is:

1. A photovoltaic system comprising:
a photovoltaic module comprising:
a generally planar substrate having a first and second major sides;
two or more photovoltaic cells with one side on the first major side of the substrate;
one or more brackets adhesively attached to an interior surface of a window with a layer of contact adhesive, wherein the one or more brackets are configured to mechanically engage the photovoltaic module to thereby hold the photovoltaic module in place with a light incident side facing the interior surface of the window.

2. The invention of claim 1, further including a release coating covering the contact adhesive.

3. The invention of claim 1, wherein a total surface area of the first side of the substrate is larger than a photovoltaically active area of the one or more photovoltaic cells, thus creating a photovoltaically non-active border area on the first side.

4. The invention of claim 3, wherein the border area is aligned under a retaining portion of the brackets allowing the photovoltaically active area of the photovoltaic cells to not be shaded by the brackets.

5. The invention of claim 3, wherein an insulated strip of material is attached to the border area of the substrate, the strip being compressed when the photovoltaic module is placed into the brackets and thus insulating the area between the photovoltaic module and window interior surface from air flow, dust particles and any other intrusions that may inhibit the function of the system.

6. The invention of claim 1, wherein the photovoltaic module is comprised of a flexible thin-film solar material having the ability to bend up to 30 degrees.

7. The invention of claim 1, wherein the photovoltaic module is comprised of a semi-flexible material having the ability to bend up to 5 degrees.

8. The invention of claim 1, wherein the photovoltaic module is held tight to and is in full contact with the window interior surface.

9. The invention of claim 1, wherein at least one of the brackets has a hole in it allowing an electrical connection to be made to the photovoltaic module.

10. The invention of claim 1, wherein a base section of the bracket is thick enough to create a space between the interior surface of the window and the window facing surface of the photovoltaic module, thus creating an open area allowing air to flow between the module and the window.

11. The invention of claim 1, wherein the mechanical engagement of the photovoltaic module to the brackets is comprised of at least one of: snaps, clasps, hook and loop fasteners, zippers, magnets, magnetic strips, metal plates, screw type, sliding connectors, and channels.

12. The invention of claim 1, wherein the photovoltaic module further comprises a mechanical attachment member partially embedded in the substrate.

13. The invention of claim 1, wherein the brackets further comprise a channel opening that is wider at an insertion point of the photovoltaic module and more narrow at a position where the photovoltaic module is fully inserted, thus creating a friction fit that holds the photovoltaic module in place once it has been fully inserted.

14. The invention of claim 1, further including a first terminal and a second terminal which are in electrical communication with the photovoltaic cells.

15. The invention of claim 14, wherein the terminals are disposed in a first electrical connector which is supported on the substrate.

16. The invention of claim 15, wherein at least one electrical conductor with a second electrical connector is plugged into the first electrical connector, wherein the conductor is extended to an electrical device or circuit.

17. The invention of claim 16, wherein the conductor is extended to a motorized window opener; wherein the photovoltaic module provides power to the motorized window opener.

18. The invention of claim 16, wherein the conductor is extended to a motorized window covering; wherein the photovoltaic module provides power to the motorized window covering.

19. The invention of claim 1, wherein the window is a sliding door with at least one section of transparent glazing material.

20. The invention of claim 1, wherein the photovoltaic system further comprises a sheet of material that looks visually similar to the substrate; whereby the sheet of material is deployed adjacent to the substrate by attachment to the interior surface of the window with contact adhesive.
